(19) United States
(12) Patent Application Publication
(10) Pub. No.: US 2026/0005192 A1
(43) Pub. Date: Jan. 1, 2026

(54) ELECTRONIC DEVICE AND A METHOD FOR FORMING THE SAME

(71) Applicant: STATS ChipPAC Pte. Ltd., Singapore (SG)

(72) Inventors: JinHee JUNG, Incheon (KR); HeeSoo LEE, Incheon (KR); EunHee MYUNG, Gyeonggi-do (KR)

(21) Appl. No.: 19/253,940

(22) Filed: Jun. 29, 2025

(30) Foreign Application Priority Data
Jun. 28, 2024 (CN) 202410858544.5

(51) Int. Cl. H01L 23/00

(52) U.S. Cl. CPC H01L 24/81; H01L 24/16; H01L 2224/16245; H01L 2224/81002; H01L 2224/81005; H01L 2224/81097; H01L 2224/81203; H01L 2224/81224; H01L 2224/81815; H01L 2924/3511; H01L 2924/401

(57) ABSTRACT

A method for forming an electronic device is provided. The method comprises: providing a light pervious carrier having on its front surface an auxiliary layer; forming conductive patterns on the auxiliary layer; disposing at least one electronic component on at least a portion of the conductive patterns via solder bumps; exposing the auxiliary layer to a light source through the light pervious carrier to heat the auxiliary layer and reflow the solder bumps; forming a mold cap on the auxiliary layer to encapsulate the conductive patterns and the at least one electronic component to form the electronic device; and removing the auxiliary layer and the light pervious carrier from the electronic device to expose the conductive patterns.

### TECHNICAL FIELD

The present application generally relates to semiconductor technology, and more particularly, to an electronic device and a method for forming the electronic device.

### BACKGROUND OF THE INVENTION

The semiconductor industry is constantly faced with complex integration challenges as consumers want their electronics to be smaller, faster and higher performance with more and more functionalities packed into a single device. Typically, a semiconductor packaging and assembling process may include attaching an electronic component, such as a semiconductor chip, onto conductive pads on a substrate with solder bumps disposed therebetween. A heating process may be applied to reflow the solder bumps, and thus bond the electronic component onto the substrate.

In some cases, substrates may be not desired for electronic devices, i.e., electronic components of the electronic devices may be integrally formed with conductive patterns using mold caps or similar encapsulants. The substrate free electronic devices have advantages in reducing device warpage during a packaging process and minimizing a package size. However, a current bonding technique for bonding the electronic component with the conductive patterns may be ineffective and may potentially cause defects in the electronic device so produced.

Therefore, a need exists for applying an effective bonding technique to form substrate free electronic devices.

### SUMMARY OF THE INVENTION

An objective of the present application is to provide a method for applying an effective bonding technique to form substrate free electronic devices.

According to an aspect of the present application, a method for forming an electronic device is provided. The method comprises: providing a light pervious carrier having on its front surface an auxiliary layer; forming conductive patterns on the auxiliary layer; disposing at least one electronic component on at least a portion of the conductive patterns via solder bumps; exposing the auxiliary layer to a light source through the light pervious carrier to heat the auxiliary layer and reflow the solder bumps; forming a mold cap on the auxiliary layer to encapsulate the conductive patterns and the at least one electronic component to form the electronic device; and removing the auxiliary layer and the light pervious carrier from the electronic device to expose the conductive patterns.

It is to be understood that both the foregoing general description and the following detailed description are exemplary and explanatory only, and are not restrictive of the invention. Further, the accompanying drawings, which are incorporated in and constitute a part of this specification, illustrate embodiments of the invention and together with the description, serve to explain the principles of the invention.

### BRIEF DESCRIPTION OF DRAWINGS

The drawings referenced herein form a part of the specification. Features shown in the drawing illustrate only some embodiments of the application, and not of all embodiments of the application, unless the detailed description explicitly indicates otherwise, and readers of the specification should not make implications to the contrary.

FIGS. 1A to 1G illustrate various steps of a method for forming an electronic device according to a first embodiment of the present application.

FIG. 2 illustrates a laser radiation step to heat the auxiliary layer and reflow the solder bumps in a method for forming an electronic device according to a second embodiment of the present application.

The same reference numbers will be used throughout the drawings to refer to the same or like parts.

### DETAILED DESCRIPTION OF THE INVENTION

The following detailed description of exemplary embodiments of the application refers to the accompanying drawings that form a part of the description. The drawings illustrate specific exemplary embodiments in which the application may be practiced. The detailed description, including the drawings, describes these embodiments in sufficient detail to enable those skilled in the art to practice the application. Those skilled in the art may further utilize other embodiments of the application, and make logical, mechanical, and other changes without departing from the spirit or scope of the application. Readers of the following detailed description should, therefore, not interpret the description in a limiting sense, and only the appended claims define the scope of the embodiment of the application.

In this application, the use of the singular includes the plural unless specifically stated otherwise. In this application, the use of “or” means “and/or” unless stated otherwise. Furthermore, the use of the term “including” as well as other forms such as “includes” and “included” is not limiting. In addition, terms such as “element” or “component” encompass both elements and components including one unit, and elements and components that include more than one subunit, unless specifically stated otherwise. Additionally, the section headings used herein are for organizational purposes only, and are not to be construed as limiting the subject matter described.

As used herein, spatially relative terms, such as “beneath”, “below”, “above”, “over”, “on”, “upper”, “lower”, “left”, “right”, “vertical”, “horizontal”, “side” and the like, may be used herein for ease of description to describe one element or feature's relationship to another element(s) or feature(s) as illustrated in the Figures. The spatially relative terms are intended to encompass different orientations of the device in use or operation in addition to the orientation depicted in the Figures. The device may be otherwise oriented (rotated 90 degrees or at other orientations) and the spatially relative descriptors used herein may likewise be interpreted accordingly. It should be understood that when an element is referred to as being “connected to” or “coupled to” another element, it may be directly connected to or coupled to the other element, or intervening elements may be present.

As mentioned above, electronic components of some electronic devices may be integrally formed with conductive patterns such as conductive pads using mold caps or similar encapsulants, instead of using substrates. The substrate free electronic devices may have advantages in reducing device warpage during a packaging process and minimizing a package size. Typically, a laser assisted bonding (LAB) technique may be applied to bond the electronic components onto the conductive pads with improved temperature control. During an LAB bonding process, a laser source emits a laser beam, which may directly reach the electronic components and then heat and reflow solder bumps between the electronic components and the conductive patterns, so as to form an electrical connection therebetween. However, the inventors of the present application noticed that in some cases that electronic components of such electronic devices may have different sizes, laser energy received by the solder bumps below the different sized electronic components during the LAB process may be quite different, thereby resulting in an undesired temperature variation among the solder bumps.

To address this issue, a new method for forming an electronic device is provided. A light pervious carrier with an auxiliary layer thereon is provided. Next, conductive patterns are formed on the auxiliary layer, and at least one electronic component is disposed on the conductive patterns via solder bumps. Next, a laser beam is emitted to the auxiliary layer from its back side through the light pervious carrier to heat the auxiliary layer and reflow the solder bumps. As such, the auxiliary layer may receive a generally uniform laser radiation, and convert the laser energy further into heat in a more uniform distribution across the auxiliary layer. Thus, the solder bumps on the auxiliary layer can be heated and reflowed more uniformly. The auxiliary layer and the light pervious carrier may be removed in a subsequent step. In this way, an electronic device without a substrate can be formed with an improved bonding quality.

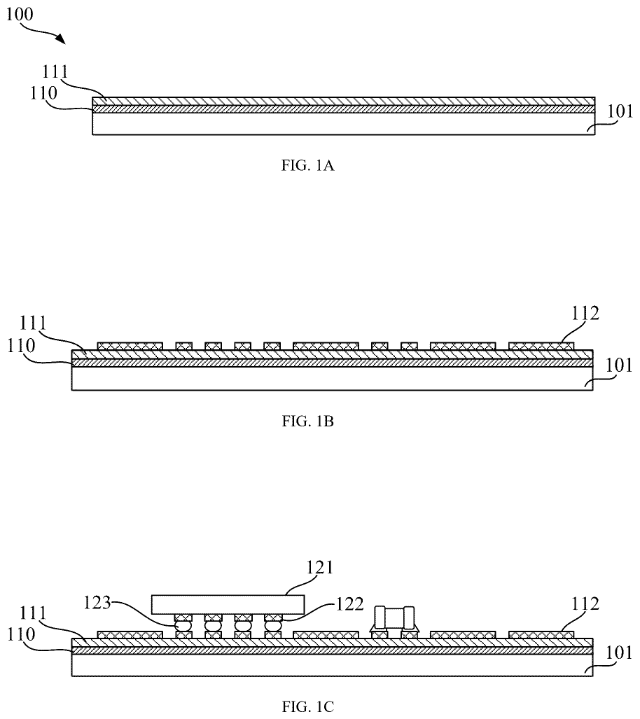

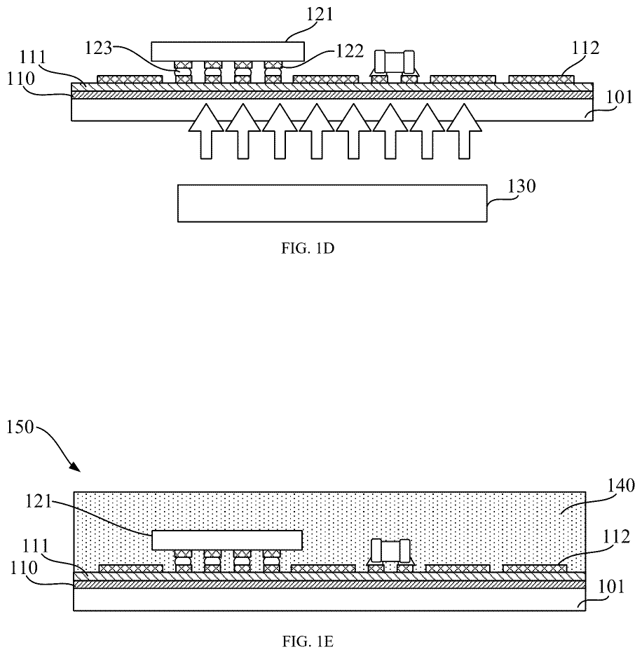

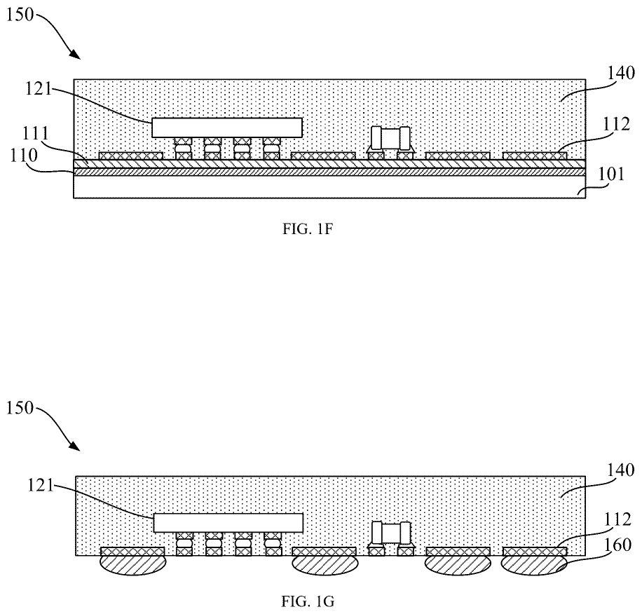

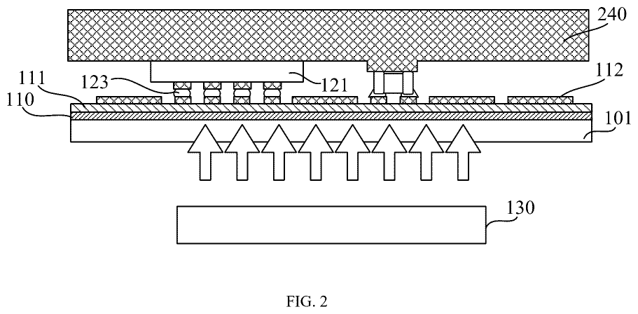

FIGS. 1A to 1G illustrate various steps of a method for forming an electronic device according to a first embodiment of the present application. The electronic device formed using the method is shown in FIG. 1G.

As shown in FIG. 1A, a carrier assembly 100 is provided, which may serve as a platform to form an electronic device thereon. In some embodiments, the carrier assembly 100 may include a copper clad laminate (CCL) layer having a light pervious carrier 101 and an auxiliary layer disposed on a front surface of the light pervious carrier 101. The light pervious carrier 101 may include a transparent material such as a glass material or a quartz material which allows a laser beam to pass therethrough. The auxiliary layer may include a metal material, for example, a copper layer, which may facilitate subsequent formation of conductive patterns thereon and may also be contributive to a bonding process to form an electronic device.

In the embodiment shown in FIG. 1A, the auxiliary layer further includes a first auxiliary film 110 formed on and being in contact with the light pervious carrier 101, and a second auxiliary film 111 attached on the first auxiliary film 110. In particular, the first auxiliary film 110 may include a copper foil and the second auxiliary film 111 may include another copper foil which is the same as the copper foil of the first auxiliary film 110. In some embodiments, the second auxiliary film 111 may be attached on the first auxiliary film 110 through electrostatic attraction, to form a temporary connection with the first auxiliary film 110. For example, an electrostatic generator may be coupled to the second auxiliary film 111 to generate static electricity in the second auxiliary film 111 before or during a step when the second auxiliary film 111 is attached onto the first auxiliary film 110. As such, the second auxiliary film 111 may adhere to the first auxiliary film 110 through the electrostatic attraction when it gets close to the first auxiliary film 110. The electrostatic attraction may provide temporary adherence between the first auxiliary film 110 and the second auxiliary film 111, which can be easily separated when the first auxiliary film 110 and the second auxiliary film 111 are pull away from each other.

Furthermore, a back surface of the second auxiliary film 111 and/or a front surface of the first auxiliary film 110 may be a rough surface formed by a knurling tool, which enhances the adherence between the auxiliary films 110 and 111. In some embodiments, an adhesive material may be further applied between the first auxiliary film 110 and the second auxiliary film 111 to provide additional adherence. In some embodiments, an adhesive interlayer may be applied between the light pervious carrier 101 and the first auxiliary film 110 such that the first auxiliary film 110 may firmly adhere to the light pervious carrier 101. It should be noted that the adherence between the light pervious carrier 101 and the first auxiliary film 110 may be stronger than the adherence between the first auxiliary film 110 and the second auxiliary film 111, which allows the carrier assembly 100 to be separated at an interface between the first auxiliary film 110 and the second auxiliary film 111 when exposed to an external force, which will be elaborated later.

The auxiliary films 110 and 111 can be temporarily connected together in other manners. In some alternative embodiments, at least one of the first auxiliary film 110 and the second auxiliary film 111 may include a ferromagnetic material, such that the first auxiliary film 110 and the second auxiliary film 111 may be attached to each other through magnetic attraction.

The second auxiliary film 111 may also serve as a seed layer for the formation of conductive patterns thereon. Therefore, a material of the second auxiliary film 111 may be selected to have good compatibility with the conductive patterns to be formed. In some embodiments, the second auxiliary film 111 may include a different material from the first auxiliary film 110. As such, the first auxiliary film 110 may be designed to allow a better adherence with the light pervious carrier 101, and the second auxiliary film 111 may designed to allow a better formation of the conductive patterns.

Furthermore, the auxiliary layer mentioned above may be a double-layer structure or a multi-layer structure. Alternatively, in some embodiments, the auxiliary layer may also be formed as a single piece instead of such laminated structure. The auxiliary layer may adhere to the light pervious carrier through an adhesion material therebetween, for example.

In some embodiments, the carrier assembly 100 may be commercially available for a vendor. For example, the carrier assembly 100 may be a copper clad laminate. It can also be appreciated that the carrier assembly 100 may be formed by laminating two or more layers in a site where other subsequent processing step may be performed, which may allow for better customized designs, such as a customized material composition or structure of the auxiliary layer.

Next, as shown in FIG. 1B, conductive patterns 112 are formed on the auxiliary layer, or particularly the first auxiliary film 111. The conductive patterns 112 may include copper, nickel or their combination, or any other suitable conductive materials. As mentioned above, the conductive patterns 112 may include a material which is the same as or similar to that of the second auxiliary film 111, such that the second auxiliary film 111 can guide and facilitate a formation of the conductive patterns 112 thereon. To be more specific, a conductive material layer may first be formed on the second auxiliary film 111 to serve as an ingredient to form the conductive patterns 112. Next, a mask layer with openings passing therethrough may be formed on a top surface of the conductive material layer to define a layout of the conductive patterns 112 to be formed. Next, an etching process may be implemented to remove at least a portion of the conductive material layer exposed from the openings of the mask layer, and thus forms the conductive patterns 112. It can also be appreciated that the removing process may be implemented by other techniques such as laser ablation, milling, drilling, pinching or their combinations, or any other suitable processing.

Next, as shown in FIG. 1C, at least one electronic component 121 is disposed on at least a portion of the conductive patterns 112 via solder bumps 123. The at least one electronic component 121 may include conductive pads 122 on its back surface, which are aligned with a portion of the conductive patterns 112. To be more specific, a solder bump material including metal powers may be disposed or dispensed on the conductive patterns 112. Then the at least one electronic component 121 may be disposed on the conductive patterns 112 with a solder bump material disposed between one of the conductive patterns 112 and a respective one of the conductive pads 122 of the at least one electronic component 121.

In some embodiments, the electronic component 121 may include a semiconductor die. In some other embodiments, the electronic component 121 may include various types of electronic modules, such as semiconductor chips, resistors, capacitors or other integrated circuit chips. Furthermore, as shown in FIG. 1C, more than one electronic component 121 is mounted on the conductive patterns 112, where the electronic components 121 have various sizes and layouts. In some embodiments, a flux material may further be applied within the solder bump material or dispensed to the conductive patterns 112 to facilitate a subsequent bonding process.

Next, a light source, such as a laser source 130 may be disposed below the light pervious carrier 101 to emit a laser beam to bond the at least one electronic component 121 onto the conductive patterns 112.

As shown in FIG. 1D, the laser source 130 is turned on to emit a laser beam, which passes through the light pervious carrier 101 and is directly irradiated to the first auxiliary film 110 and the second auxiliary film 111. In this way, a sufficient amount of laser radiation can reach the first auxiliary film 110 and the second auxiliary film 111. Since the first auxiliary film 110 and the second auxiliary film 111 may include a metal material such as copper, it can effectively absorb the laser energy and be heated to a relatively high temperature in a short period of time. A sufficient amount of the absorbed energy may then be transferred to the conductive patterns 112 and the solder bumps 123 between the conductive patterns 112 and the at least one electronic component 121, such that the solder bumps 123 can be heated and reflowed to form an electrical connection between the at least one electronic component 121 and the conductive patterns 112. Since each of the first auxiliary film 110 and the second auxiliary film 111 is formed of a uniform material, the auxiliary layer including the first auxiliary film 110 and the second auxiliary film 111 may have a uniform temperature distribution, which may serve as a uniform heating media. As such, the solder bumps 123 disposed at different positions on the conductive patterns 112 may be heated uniformly by the auxiliary layer, which facilitates a uniform reflowing of all the solder bumps 123 and thereby contributes to an improved bonding quality between the at least one electronic component 121 and the conductive patterns 112.

In particular, in some embodiments where more than one electronic component 121 with various sizes and layouts are mounted on the conductive patterns 112, the heating of the solder bumps 123 below different electronic components 121 may not be impacted by the various sizes and layouts of the electronic components 121 since the solder bumps 123 are heated from the auxiliary layer below, rather than from the above. Therefore, a uniform bonding between the electronic components 121 and the conductive patterns 112 can be formed despite of the various structures of the electronic components 121. Moreover, since the auxiliary layer may have a uniform temperature distribution, warpage issues of the auxiliary layer and an electronic device so produced may be reduced after the bonding process. In addition, the laser assisted bonding process allows for a more rapid heating and cooling of the auxiliary layer, which helps to better control a temperature of the solder bumps 123 during the bonding process. In this way, solder bumps 123 with desired shapes and heights may be formed, which improves the bonding quality of the so produced electronic device, especially for cases where the solder bumps 123 may be reflowed within a relatively narrow gap between the at least one electronic component 121 and the conductive patterns 112.

Furthermore, in some other embodiments, the laser source 130 may emit laser beams separately to heat and reflow the solder bumps 123 below the different sized electronic components 121 in a customized way. To be more specific, the laser source 130 may move to different positions or change emitting directions of the laser beam to pass through different portions of the light pervious carrier 101. As such, the solder bumps 123 below the different sized electronic components 121 may be heated individually with customized laser bonding processes, such as various laser energy or heating duration, rather than being heated together in a same laser radiation process. In this way, a reflowing process of the solder bumps 123 below the electronic components 121 may be controlled more precisely. The reflowed solder bumps 123 with controlled heights and structures may be achieved, thereby improving the quality of the solder bumps 123 for the different sized electronic components 121.

In some embodiments, the auxiliary layer including the first auxiliary film 110 and the second auxiliary film 111 may be designed to have a sufficient thickness which can absorb an abundant amount of heat energy from the laser beam, thereby providing enough heat energy to heat and reflow the solder bumps 123. In some preferred embodiments, the thickness of the first auxiliary film 110 may be 5 μm˜60 μm, and the thickness of the second auxiliary film 111 may be 1 μm˜10 μm.

Next, as shown in FIG. 1E, a mold cap 140 is formed on the second auxiliary film 111 to encapsulate the conductive patterns 112 and the at least one electronic component 121 to form the electronic device 150. The electronic device 150 includes the conductive patterns 112, the at least one electronic component 121 bonded thereon and the mold cap 140. To be more specific, the mold cap 140 is formed using a molding process such as an injection molding process, which covers respective front surfaces of the conductive patterns 112, the at least one electronic component 121 and an exposing portion of the second auxiliary film 111 for encapsulation. The mold cap 140 material includes epoxy, polyester resin, etc. In some embodiments, the mold cap 140 may be formed using other various molding technologies, including a transfer molding process, a compression molding process or a film-assisted molding (FAM) process.

Next, the light pervious carrier 101 is removed from the electronic device 150. As shown in FIG. 1F, the light pervious carrier 101 may be mechanically detached from the electronic device 150 at an interface between the first auxiliary film 110 and the second auxiliary film 111 by an external force. In some embodiments, the electronic device 150 which is formed on the second auxiliary film 111 may be fixed by a holding apparatus, for example, a clamping claw or a chuck. It can also be appreciated that a container may be used to accommodate and fix the electronic device 150. Then an external force may be applied to the light pervious carrier 101, for example, by a chuck to move the light pervious carrier 101 away from the electronic device 150. Alternatively, the light pervious carrier 101 may be fixed and an external force may be applied to the electronic device 150, for example, to the mold cap 140. As mentioned above, since the adherence between the light pervious carrier 101 and the first auxiliary film 110 may be stronger than the adherence between the first auxiliary film 110 and the second auxiliary film 111, the adherence between the first auxiliary film 110 and the second auxiliary film 111 may be broken first while the first auxiliary film 110 still adheres to the light pervious carrier 101. In this way, the light pervious carrier 101 and the first auxiliary film 110 may be separated and removed from the second auxiliary film 111 and the electronic device 150 formed thereon. It should be noted that a magnitude of the external force applied to separate and remove the light pervious carrier 101 from the electronic device 150 may be adjusted according to the adherence between the first auxiliary film 110 and the second auxiliary film 111.

In some embodiments where the second auxiliary film 111 is attached on the first auxiliary film 110 through electrostatic attraction which is generated by an electrostatic generator, the electrostatic generator may further generate opposite static electricity to counteract the originally generated static electricity, thereby eliminating the electrostatic attraction. As such, the light pervious carrier 101 may be separated from the electronic device 150 more easily.

In some embodiments where an adhesion material is included between the first auxiliary film 110 and the second auxiliary film 111, a solution may be applied to dissolve the adhesion material before mechanically detaching the light pervious carrier 101 from the electronic device 150.

Next, as shown in FIG. 1G, the second auxiliary film is removed from back surfaces of the mold cap 140 and the conductive patterns 112 so as to expose the conductive patterns 112, thereby forming the electronic device 150 without processing accessories. The at least one electronic component 121 included within the electronic device 150 can be directly mounted on the conductive patterns 112 without a substrate. The substrate-free electronic device 150 may have a minimized package height and a reduced warpage risk, which contributes to an improved integration level and electrical reliability.

In some embodiments, the second auxiliary film 111 may be removed by an etching process. In some other embodiments, the second auxiliary film 111 may be removed by using a planarization technique, such as a chemical mechanical polishing (CMP) process or a grinding process.

In some other embodiments, the light pervious carrier 101 can also be mechanically removed from the electronic device 150 at an interface between the first auxiliary film 110 and the light pervious carrier 101. Then the first auxiliary film 110 can be removed together with the second auxiliary film 111 to expose the back surfaces of the conductive patterns 112 and the mold cap 140.

The auxiliary layer mentioned above may be a double-layer structure. Alternatively, in some embodiments, the auxiliary layer may be formed as a single piece. The light pervious carrier 101 may be separated and removed from the electronic device 150 at an interface between the light pervious carrier 101 and the auxiliary layer, and then the auxiliary layer may be removed from the electronic device 150.

Next, additional solder bumps 160 may be formed on the back surface of at least a portion of the conductive patterns 112 for mounting the electronic device 150 onto external electronic modules. Since the conductive patterns 112 are in direct contact with the additional solder bumps 160, an electrical connecting pathway may be shortened and simplified, which allows for more efficient signal transmission from the electronic device 150 to the external electronic modules.

FIG. 2 illustrates a laser radiation step to heat an auxiliary layer and reflow solder bumps in a method for forming an electronic device according to a second embodiment of the present application. The step illustrated in FIG. 2 may be implemented after the steps illustrated in FIGS. 1A to IC have been performed, instead of the step illustrated in FIG. 1D, and the steps illustrated in FIGS. 1E to 1G may be performed after the step illustrated in FIG. 2. Therefore, details of the other steps may be referred to the embodiment described with reference to FIGS. 1A to 1G and will not be elaborated below.

In particular, after the at least one electronic component 121 have been disposed on the conductive patterns 112 via solder bumps 123, which is illustrated in FIGS. 1A to IC, a laser source 130 may be disposed below the light pervious carrier 101 to emit a laser beam to bond the at least one electronic component 121 onto the conductive patterns 112. In this embodiment, the laser source 130 may be similar to that illustrated in FIG. 1D.

As shown in FIG. 2, the laser source 130 is turned on to emit a laser beam passing through the light pervious carrier 101 to the first auxiliary film 110 and the second auxiliary film 111 to heat the first and the second auxiliary film 110, 111 and reflow the solder bumps 123. During this process, the at least one electronic component 121 may be pressed downwards against the first auxiliary film 110 and the second auxiliary film 111 via a press bar 240. In some embodiments where more than one differently sized electronic components 121 are mounted on the carrier 101, the press bar 240 may be formed to have a profile which matches with the different heights of the electronic components 121 at different positions of the press bar 240. For example, the press bar 240 or a bottom portion of the press bar 240 may be made of a thermoset material that may be reshaped to the profile matching with the electronic components 121 through a press step at a thermoset temperature. Furthermore, the press bar 240 may be pre-heated to a certain higher temperature, for example, 70° C.˜120° C., before the laser radiation step. As such, the temperature of the pre-heated press bar 240 may be closer to a required temperature for the bonding through the solder bumps 123. Then during the bonding process, the press bar 240 is in direct contact with the at least one electronic component 121, which facilitates the reflowing process of the solder bumps 123 and reduces potential warpage issues.

After the at least one electronic component 121 is bonded onto the conductive patterns 112, the steps illustrated in FIGS. 1E to 1G may be performed to form an electronic device.

While the exemplary method for forming an electronic device of the present application is described in conjunction with corresponding figures, it will be understood by those skilled in the art that modifications and adaptations to the method for forming an electronic device may be made without departing from the scope of the present invention.

Various embodiments have been described herein with reference to the accompanying drawings. It will, however, be evident that various modifications and changes may be made thereto, and additional embodiments may be implemented, without departing from the broader scope of the invention as set forth in the claims that follow. Further, other embodiments will be apparent to those skilled in the art from consideration of the specification and practice of one or more embodiments of the invention disclosed herein. It is intended, therefore, that this application and the examples herein be considered as exemplary only, with a true scope and spirit of the invention being indicated by the following listing of exemplary claims.

1. A method for forming an electronic device, the method comprising:
providing a light pervious carrier having on its front surface an auxiliary layer;
forming conductive patterns on the auxiliary layer;
disposing at least one electronic component on at least a portion of the conductive patterns via solder bumps;
exposing the auxiliary layer to a light source through the light pervious carrier to heat the auxiliary layer and reflow the solder bumps;
forming a mold cap on the auxiliary layer to encapsulate the conductive patterns and the at least one electronic component to form the electronic device; and
removing the auxiliary layer and the light pervious carrier from the electronic device to expose the conductive patterns.

2. The method of claim 1, wherein the auxiliary layer comprises a metal material.

3. The method of claim 1, wherein the auxiliary layer comprises:
a first auxiliary film formed on the light pervious carrier; and
a second auxiliary film attached on the first auxiliary film.

4. The method of claim 3, wherein the second auxiliary film is attached on the first auxiliary film through electrostatic attraction.

5. The method of claim 3, wherein a material of the first auxiliary film is the same as a material of the second auxiliary film.

6. The method of claim 5, wherein the first auxiliary film comprises a copper foil, and the second auxiliary film comprises another copper foil.

7. The method of claim 4, wherein the auxiliary layer further comprises: an adhesive material applied between the first auxiliary film and the second auxiliary film.

8. The method of claim 3, wherein the second auxiliary film is attached on the first auxiliary film through an adhesive material.

9. The method of claim 3, wherein removing the auxiliary layer and the light pervious carrier from the mold cap comprises:
mechanically detaching the light pervious carrier from the electronic device at an interface between the first auxiliary film and the second auxiliary film; and
removing the second auxiliary film from the electronic device.

10. The method of claim 1, wherein after removing the auxiliary layer and the light pervious carrier from the mold cap, the method further comprises:
forming additional solder bumps on the conductive patterns.

11. The method of claim 1, wherein forming conductive patterns on the auxiliary layer comprises:
forming a conductive material layer on the auxiliary layer; and
removing at least a portion of the conductive material layer to form the conductive patterns.

12. The method of claim 1, wherein the light pervious carrier comprises glass or quartz.

13. The method of claim 1, wherein the electronic component comprises a semiconductor die.

14. An electronic device which is formed using the method of claim 1.
